(19) United States
(12) Patent Application Publication
(10) Pub. No.: US 2015/0207508 A1
(43) Pub. Date: Jul. 23, 2015

(54) LEVEL CONVERSION CIRCUIT

(71) Applicant: The Regents of The University of Michigan, Ann Arbor, MI (US)

(72) Inventors: Allan Ailun WANG, Ann Arbor, MI (US); David Theodore Blaauw, Ann Arbor, MI (US); Dennis Michael Sylvester, Ann Arbor, MI (US)

(73) Assignee: The Regents of The University of Michigan, Ann Arbor, MI (US)

(21) Appl. No.: 14/161,038

(22) Filed: Jan. 22, 2014

(51) Int. Cl. H03K 19/0185

(52) U.S. Cl. CPC H03K 19/018507

(57) ABSTRACT

A level conversion circuit has a keeper circuit for retaining an intermediate output node at a high output level to avoid it floating due to leakage through a pullup transistor in a shifting circuit. Thin oxide and thick oxide versions of the level conversion circuit can be provided. The level conversion circuit enables higher performance, reduced power consumption and reduced susceptibility to process variation compared to previous level conversion designs.

### TECHNICAL FIELD

The present technique relates to the field of integrated circuits. More particularly, the present technique relates to a level conversion circuit.

### BACKGROUND

An integrated circuit may have different portions operating in different voltage domains. A level conversion circuit may be used to convert a signal from the voltage levels used in one domain to the voltage levels used in another domain. The present technique seeks to provide an improved level conversion circuit.

### SUMMARY OF THE PRESENT TECHNIQUE

Viewed from one aspect, the present technique provides a level conversion circuit for generating an output signal in response to an input signal, the input signal having one of a high input level and a low input level, and the output signal having one of a high output level and a low output level; the level conversion circuit comprising:

(a) a shifting circuit configured to generate a shifted signal in response to the input signal, the shifted signal having one of the high output level and an intermediate level between the high output level and the high input level;

the shifting circuit comprising a first pullup transistor configured to enter a conductive state to pull the shifted signal to the high output level when the input signal has a first input level comprising one of the low input level and the high input level, and to enter a less conductive state to allow the shifted signal to drop to the intermediate level when the input signal has a second input level comprising the other of the low input level and the high input level;

(b) a second pullup transistor configured to enter a conductive state to pull an intermediate output node to the high output level when the shifted signal has the intermediate level, and to enter a less conductive state when the shifted signal has the high output level;
(c) a pulldown transistor configured to enter a conductive state to pull the intermediate output node to the low output level when the input signal has said first input level, and to enter a less conductive state when the input signal has said second input level;
(d) an output buffer configured to generate the output signal based on the signal at the intermediate output node; and
(e) a keeper circuit configured to retain the intermediate output node at the high output level when the input signal has said second input level.

The level conversion circuit converts an input signal having one of a high input level and a low input level into an output signal having one of a high output level and a low output level. The level conversion circuit comprises a shifting circuit which generates a shifted signal having one of the high output level and an intermediate level, with the intermediate level being between the high output level and high input level. The shifting circuit includes a first pullup transistor which pulls the shifted signal to the high output level when the input signal has a first input level (one of the low and high input level) and enters a less conductive state to allow the shifted signal to drop to the intermediate level when the input signal has a second input level (the other of the low and high input level). A second pullup transistor and pulldown transistor are provided to pull an intermediate output node to the high output level and low output level respectively. The second pullup transistor is controlled using the shifted signal generated by the shifting circuit, while the pulldown transistor is controlled using the input signal or a signal derived from the input signal. This circuit arrangement allows the intermediate output node to swing across the full range between the high output level and low output level in response to an input signal swinging between the low input level and high input level, and provides relatively high performance across process corners and local variation compared to other level converting designs. An output buffer then generates the final output signal based on the signal at the intermediate output node.

However, a problem arises when the input signal has the second input level. At this time, the first pullup transistor is in the less conductive state and so the shifted signal drops to the intermediate level to turn on the second pullup transistor. However, if the input signal remains at the same level for some time, then eventually leakage through the first pullup transistor will cause the shifted signal to rise back up to the high output level, making the second pullup transistor less conductive. When the input signal is at the second input level, the pulldown transistor is also in the less conductive state, and so this may cause the intermediate output node to float because neither of second pullup transistor and pulldown transistor would be on. This could cause reduced performance and incorrect generation of the output signal, which could lead to errors in downstream circuits which use the output signal.

To address this problem, a keeper circuit is provided to retain the intermediate output node at the higher output level when the input signal has the second input level, so that the intermediate output node cannot float. If a keeper circuit was provided to hold the shifted signal node at the required level, rather than the intermediate output node, then the efficiency of the shifted circuit would be reduced and the second pullup transistor and pulldown transistor would switch more slowly. The keeper circuit provided at the intermediate output node provides an improved level conversion circuit because it enables faster switching of the level conversion circuit while avoiding the problem of the floating intermediate output node discussed above.

The shifting circuit may have a capacitor coupled between a shifted signal node for carrying the shifted signal and an input node for carrying the input signal or a complementary input signal (an inverted version of the input signal). The capacitive coupling provided by the capacitor enables the shifted signal to be generated with the intermediate level between the high input level and high output level. When the input signal or complementary input signal is high, then a first plate of the capacitor is charged to the high input level, and a second plate of the capacitor is charged to the high output level using the first pullup transistor. When the input signal or complementary input signal switches low, then the first plate of the capacitor is discharged to the low input level and this causes the second plate to drop to the intermediate level between the high input level and high output level. Typically, the intermediate level may correspond to the difference between the high output level and high input level. Generating the shifted signal using a capacitor in this way enables a simpler circuit arrangement for the level conversion circuit with reduced static power consumption compared to other level conversion designs.

The capacitor may be implemented in various forms. However, it can be useful to provide a capacitor in the form of a metal on silicon field effect transistor (MOSFET), because this tends to have reduced circuit area compared to other forms of capacitor.

In general, the shifting circuit may comprise first and second complementary circuits which generate complementary shifted signals. Each of the complementary circuits may have a respective capacitor and first pullup transistor, and the first and second complementary circuits may be responsive to the input signal and a complementary input signal respectively. The second pullup transistor may receive the shifted signal generated by either of the first and second complementary circuits. The first and second complementary circuits may be cross coupled so that the first pullup transistor of one complementary circuit has its gate terminal coupled to the shifted signal node of the other complementary circuit, and vice versa. This cross coupled design allows each capacitor to be charged and discharged in the way discussed above.

The keeper circuit may have various forms. For example, the keeper circuit may have a keeper control transistor which enters a conductive state when the input signal has the second input level and enters a less conductive state when the input signal has the first input level. However, as the input signal switches between the low input level and high input level, while the keeper circuit acts in the output domain, it is preferable to control the keeper circuit using a signal switching between the low output level and high output level. For example, a complementary version of the signal at the intermediate output node can be used to control the keeper control transistor to switch between states. While this complementary signal could be generated in many ways, it can be convenient to use the output buffer to provide the complementary version of the signal at the intermediate output node. The output buffer is typically already provided for generating a stronger output signal, and so this signal can be reused to control the keeper control transistor, so that it is not necessary to provide further circuitry for generating the control signal for the keeper control transistor.

The keeper circuit helps maintain correct operation when the input signal has the second input level. However, when the input signal switches to the first input level then the pulldown transistor will turn on and may have to fight against the keeper circuit for some time before the keeper circuit is turned off. To ensure that the pulldown transistor can overcome the pull of the keeper circuit, it can be useful to provide a pulldown transistor which passes a larger current when in the conductive state than the current passed by the keeper circuit when it retains the intermediate output node at the high output level. For example, the relative widths of the transistors in the keeper control circuit and the pulldown transistor can be selected to ensure a greater drive strength for the pulldown transistor than the keeper circuit.

It would be possible to provide the keeper circuit with a fixed drive strength, for example by making the keeper control transistor narrower than the pulldown transistor. However, if the relative drive strength is fixed, then process variation or other conditions may affect the relative drive strengths, and could prevent the circuit working as desired. Therefore, a more flexible approach allows for varying drive strength of the keeper circuit. The keeper circuit may be provided with a current regulating transistor in series with the keeper control transistor. The current regulating transistor may limit the current passing through the keeper control transistor when in the conductive state. The gate voltage applied to the current regulating transistor controls the current passing through the current regulating transistor and hence changes the drive strength of the keeper circuit as a whole. A tuning circuit may be provided to tune the gate voltage of the current regulating transistor so as to adjust the drive strength of the keeper circuit. If the pullup of the keeper circuit is too weak, then the functionality of the level conversion circuit is impaired since the problem discussed above with the floating intermediate output node may still arise, and so in this case the tuning circuit may adjust the gate voltage of the keeper control transistor to allow more current to pass through the keeper circuit. On the other hand, if the pullup of the keeper circuit is too strong, then the performance of the level conversion circuit will be reduced since the pulldown transistor will take longer to overcome the keeper circuit, preventing the level conversion circuit operating at high frequencies. In this case the tuning circuit can adjust the gate voltage of the current regulating transistor to allow less current to pass through the keeper circuit. Hence, the tuning circuit and current regulating transistor provide a flexible way of controlling the level conversion circuit to ensure that it operates correctly and at a sufficiently high frequency.

The arrangement discussed above can be implemented using thin oxide transistors, which is suitable for use with relatively low voltages. To allow the level conversion circuit to be used for a wide range of voltage scaling, from a near threshold supply to full I/O voltage levels, the level conversion circuit may be implemented using thicker oxide transistors. However, in this case the basic design of level conversion circuit may encounter reduced performance because in sub-threshold operation, the switching speed of transistors is exponentially dependent on the overdrive voltage (difference between the high voltage level and the threshold voltage of the transistor), and as the threshold voltage of the thick oxide devices is much larger then the overdrive voltage is reduced.

To address this problem, the second pullup transistor and pulldown transistor may be retained as thin oxide transistors, but then a pair of cascode transistors coupled in series between the second pullup and the pulldown transistor with a thicker gate oxide can be provided to protect the second pullup transistor and pulldown transistor against drain-source voltage breakdown from the higher I/O voltage levels. This enables improved performance because the second pullup and pulldown transistors will switch more quickly because they have a lower threshold voltage than the thick oxide version, but the thicker oxide cascode transistors will shield the drains of the second pullup and pulldown transistors to prevent breakdown.

The cascode transistors may be held at a gate voltage level between the high output level and low output level. This allows the cascode transistors to remain on at all times to preserve speed, but in a state which reduces the voltage applied to the drains of the second pullup and pulldown transistors.

The other elements of the level conversion circuit, such as the shifting circuit, the output buffer and the keeper circuit can also be constructed using the thicker oxide transistors. Typically, the output buffer may comprise one or more buffer stages having a pullup portion which pulls an output of the buffer stage to the high output level and a pulldown portion which pulls an output of the buffer stage to the low output level. The pullup and pulldown portions respond to opposite transitions of the intermediate output node respectively. The output signal may then be derived from the output of a final buffer stage of the one or more buffer stages. The output buffer is useful for providing an output signal which has a more reliable voltage level and stronger drive current than the signal at the intermediate output node.

In the thick oxide embodiment, it can be useful to provide the output buffer such that the pullup portion of the first buffer stage of the one or more buffer stages is coupled to a node between the second pullup transistor and the at least one pair of cascode transistors, and the pulldown portion of the first buffer stage is coupled to a node between the pulldown transistor and the at least one pair of cascode transistors. While the circuit would still work if the buffer stage was coupled directly to the intermediate output node which is internal to the cascode transistors, the intermediate output node tends to transition more slowly than the external node between the pullup transistor and cascode transistors and the external node between the pulldown transistor and cascode transistors. Therefore, performance can be improved by coupling the pullup/pulldown portions of the output buffer to the respective external nodes instead of the intermediate output node. Nevertheless, the keeper circuit may still be coupled to the intermediate output node and the keeper circuit's retention of the intermediate output node at the output high voltage level will also propagate through to the external nodes to ensure the correct output at the output buffer.

Also, in the thick oxide embodiment, the pullup portion of each buffer stage may comprise several stacked transistors in series between the output of the buffer stage and a supply node for supplying the high output level. Similarly, the pulldown portion of each buffer stage may have multiple stacked transistors in series between the output of the buffer stage and a supply node for supplying the low output level. Using series stacked devices in this way reduces the short circuit current through the buffer stage. Since the transition speed of the output signal is relatively slow in the thicker oxide embodiment, then there is a longer period when the pullup portion of the buffer stage is turning on while the pulldown portion is turning off, or vice versa. Therefore, there is an increased time when both the pullup portion and the pulldown portion may be partially on, allowing a short circuit current to flow between the high output supply node and the low output supply node. By using several series stacked devices, this short circuit current can be reduced, to reduce power consumption.

Viewed from another aspect, the present technique provides a level conversion circuit for generating an output signal in response to an input signal, the input signal having one of a high input level and a low input level, and the output signal having one of a high output level and a low output level; the level conversion circuit comprising:

(a) shifting circuit means for generating a shifted signal in response to the input signal, the shifted signal having one of the high output level and an intermediate level between the high output level and the high input level;

the shifting circuit means comprising first pullup transistor means for entering a conductive state to pull the shifted signal to the high output level when the input signal has a first input level comprising one of the low input level and the high input level, and entering a less conductive state to allow the shifted signal to drop to the intermediate level when the input signal has a second input level comprising the other of the low input level and the high input level;

(b) second pullup transistor means for entering a conductive state to pull an intermediate output node to the high output level when the shifted signal has the intermediate level, and entering a less conductive state when the shifted signal has the high output level;
(c) pulldown transistor means for entering a conductive state to pull the intermediate output node to the low output level when the input signal has said first input level, and to enter a less conductive state when the input signal has said second input level;
(d) output buffer means for generating the output signal based on the signal at the intermediate output node; and
(e) keeper circuit means for retaining the intermediate output node at the high output level when the input signal has said second input level.

Viewed from a further aspect, the present technique provides a method of generating an output signal in response to an input signal, the input signal having one of a high input level and a low input level, and the output signal having one of a high output level and a low output level; the method comprising:

(a) in response to the input signal, generating a shifted signal having one of the high output level and an intermediate level between the high output level and the high input level,

the shifted signal being generated using a shifting circuit comprising a first pullup transistor configured to enter a conductive state to pull the shifted signal to the high output level when the input signal has a first input level comprising one of the low input level and the high input level, and to enter a less conductive state to allow the shifted signal to drop to the intermediate level when the input signal has a second input level comprising the other of the low input level and the high input level;

(b) switching a second pullup transistor to a conductive state to pull an intermediate output node to the high output level when the shifted signal has the intermediate level, and to a less conductive state when the shifted signal has the high output level;
(c) switching a pulldown transistor to a conductive state to pull the intermediate output node to the low output level when the input signal has said first input level, and to a less conductive state when the input signal has said second input level;
(d) retaining the intermediate output node at the high output level using a keeper circuit when the input signal has said second input level; and
(e) generating an output signal based on the signal at the intermediate output node.

Further aspects, features and advantages of the present technique will be apparent from the following detailed description of examples, which is to be read in conjunction with the accompanying drawings.

### BRIEF DESCRIPTION OF THE DRAWINGS

FIG. 1 schematically illustrates a first example of a level conversion circuit;

FIGS. 2 to 5 illustrates operation of the level conversion circuit of FIG. 1;

FIG. 6 is a timing diagram illustrating operation of the level conversion circuit;

FIG. 7 is a table showing the states of signals in the level conversion circuit during its operation;

FIG. 8 illustrates a second example of a level conversion circuit; and

FIG. 9 is a graph showing the improved process variation tolerance of the present technique compared to previous level shifter designs.

### DESCRIPTION OF EXAMPLE EMBODIMENTS

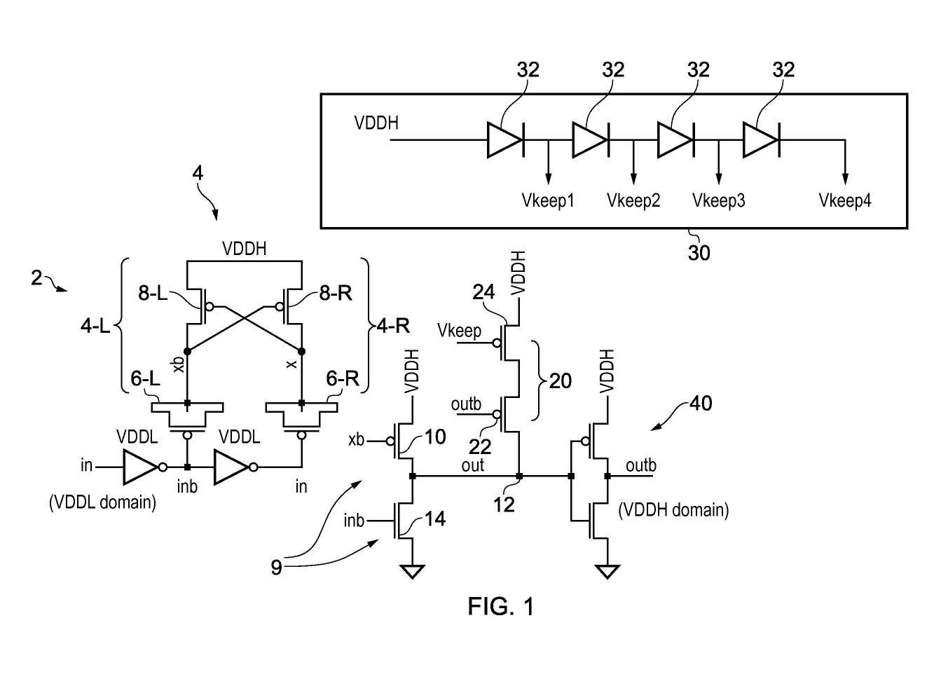

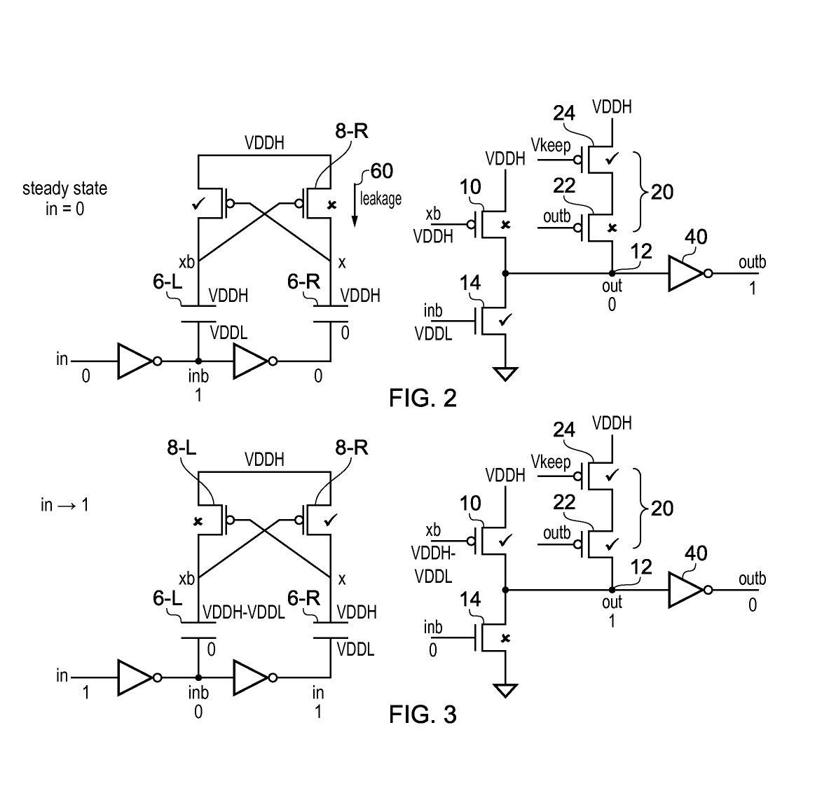

FIG. 1 illustrates an example of a level conversion circuit 2 for generating an output signal outb in response to an input signal in. The input signal is in a first voltage domain (VDDL domain) and switches between a low input level 0 and a high input level VDDL. The output signal is in a second (higher) voltage domain (VDDH domain) and switches between a low output level 0 and a high output level VDDH. The level conversion circuit has a shifting circuit 4 which generates an intermediate signal xb having one of the high output level VDDH and an intermediate level VDDH-VDDL which corresponds to the difference between the VDDH and VDDL levels of the two voltage domains. The shifting circuit 4 comprises two complementary half circuits 4-L, 4-R, each having a bootstrapping capacitor 6 and a first pullup transistor 8. In this example, the boot strapping capacitor 6 is implemented using a MOSFET (metal on silicon field effect transistor) with its gate coupled to an input node for carrying the input signal in or a complementary input node for carrying the complementary input signal inb. The source and drain of the MOSFET are coupled together and connected to the drain of the first pullup transistor 8. The capacitance between the gate and body of the MOSFET 6 acts as the capacitor in this example, but in other embodiments a different form of capacitor may be provided (FIGS. 2-5 illustrate the capacitor 6 more generally as a parallel-plate capacitor).

The two complementary half circuits 4-L, 4-R of the shifting circuit 4 are cross coupled so that the first pullup transistor 8-L, 8-R of one half circuit 4-L, 4-R is coupled to the shifted signal node x, xb of the other half-circuit 4-R, 4-L, and vice versa. The shifted signal xb generated by the left-hand complementary circuit 4-L is used to control a subsequent inverter stage 9 of the level conversion circuit 2. In other embodiments, the inverter stage 9 could receive the shifted signal x from the right hand complementary circuit 4-R instead of the shifted signal xb from the left hand complementary circuit 4-L.

The inverter stage 9 comprises a second pullup transistor 10 and a pulldown transistor 14. The second pullup transistor 10 pulls an intermediate output node 12 (out) to the VDDH level in response to the shifted signal xb being at the intermediate level VDDH-VDDL. When the shifted signal xb is at the VDDH level then the second pullup transistor 10 is turned off (less conductive). The pulldown transistor 14 is controlled by the complementary input signal inb to pull the intermediate output node 12 to ground when inb is at VDDL, and when inb is at 0 then the pulldown transistor 14 is turned off (less conductive).

A keeper circuit 20 is provided on the intermediate output node 12 to retain the intermediate output node 12 at the VDDH level. The keeper circuit 20 has a keeper control transistor 22 which turns on and off in response to a complementary output signal outb, and a current regulating transistor 24 which regulates the current passing through the keeper circuit. A tuning circuit 30 is provided to control the gate voltage Vkeep of the current regulating transistor 24. In this example, the tuning circuit 30 has a number of diodes 32 arranged in series, and different levels of the keeper voltage Vkeep can be tapped from different points of the chain of diodes 32. A selection circuit not illustrated in FIG. 1 for conciseness can select one of these alternative keeper voltages to apply to the current regulating transistor 24.

The level conversion circuit 2 also includes an output buffer 40 which comprises at least one buffer stage (only one buffer stage in the example of FIG. 1). Each buffer stage comprises an inverter which inverts the output of the preceding stage. Hence, in this example the buffer 40 inverts the intermediate output node 12 to produce the output signal outb.

FIGS. 2 to 5 schematically illustrate the operation of the level conversion circuit. FIG. 2 shows the level conversion circuit 2 in a steady state when the input signal in is at the low input level 0 (logical 0). The left hand capacitor 6-L has its plates charged to VDDL and VDDH respectively, while the right hand capacitor 6-R has its plates charged to 0 and VDDH. As xb is at VDDH and inb is at VDDL, the pulldown transistor 14 is on, and the second pullup transistor 10 is off, causing the intermediate output node 12 to be pulled low, and the output signal outb to be at VDDH (logical 1).

As shown in FIG. 3, when the input signal switches to the VDDL level (logical 1) then the complementary input inb switches to 0. At this point, the lower plate of the left hand capacitor 6-L drops to the low input level 0. The voltage difference across the capacitor 6-L remains constant, so the upper plate drops from VDDH to the intermediate level VDDH-VDDL. This causes the right hand first pullup transistor 8-R to turn on, pulling node x and the upper plate of the right hand capacitor 6-R to VDDH, and turning off the left hand first pullup transistor 8-L. Meanwhile, the lower plate of the right hand capacitor is charged to VDDL in response to the input signal in. Since the intermediate signal xb is now at the intermediate level VDDH-VDDL, which is below the threshold voltage for the second pullup transistor 10, this turns on the second pullup transistor 10, pulling the intermediate output node 12 to the VDDH level. Pulldown transistor 14 is turned off by the complementary input node inb being at 0. The output buffer 40 inverts the intermediate output signal to generate the output signal outb at logical 0 (low output level 0).

If the input signal in now remains at the high input level for some time, then ideally the state of the level conversion circuit should remain as shown in FIG. 3. However, in practice there is a leakage current 50 through the left hand first pullup transistor 8-L while it is in the less conductive state. As shown in FIG. 4, this means that the shifted signal xb gradually rises to VDDH as the upper plate of the capacitor 6-L is charged by the leakage current 50. Eventually the xb node will rise above the threshold voltage of the second pullup transistor 10, turning it off. Since the complementary input inb is at the low input value, then the pulldown transistor 14 will also be off and so if the keeper circuit 20 was not provided then the intermediate output node 12 would float, which could cause incorrect operation. The keeper circuit 20 addresses this problem because when the output signal outb is low then the keeper control transistor 22 is turned on as shown in FIG. 4, holding the intermediate output node 12 at VDDH (logical 1) to stop it from floating. Therefore, the keeper ensures correct operation even if the level conversion circuit remains in the same state for a long time. The keeper circuit 20 provided at the intermediate output node 12 provides a more efficient and higher performance solution to this problem than if a keeper had been provided at the shifted nodes xb, x of the shifting circuitry 4.

FIG. 5 shows the case when the input signal in then switches back to the low input level 0. At this point the reverse transition from the one shown in FIG. 3 occurs so that the lower plate of the left hand capacitor 6-L is now charged to VDDL while the right hand capacitor 6-R has its lower plate brought to 0 which causes its upper plate to drop to VDDH-VDDL. This turns on the left hand first pullup transistor 8-L and turns off the right hand pullup transistor 8-R. As the shifted signal xb is now at VDDH, this turns off the second pullup transistor 10 (if leakage has not already caused second pullup transistor 10 to turn off). As the complementary input node inb has risen to VDDL (logical 1), then this turns on the pulldown transistor 14. However, initially when the pulldown transition 14 turns on then the keeper circuit 20 is also still on, and so the pulldown transistor must fight the keeper circuit 20. To allow the pulldown transistor 40 to overcome the keeper circuit 20, the current regulating transistor 24 is provided and the gate voltage Vkeep of the current regulating transistor 24 is tuned using the tuning circuit 30 so that the pulldown transistor 14 will pass a greater current than the keeper circuit 20. The tuning circuit 30 helps account for process variation or other factors which vary the drive strength of the transistors, so that the pulldown transistor 14 can be made to be stronger than the keeper circuit 20. Hence, the pulldown transistor 14 will overcome the keeper circuit 20 and pull the intermediate output node 12 low, causing the complementary signal generated by the output buffer 14 to go high eventually turning off the keeper control transistor 22 so that the keeper circuit 20 no longer retains the intermediate node 12 at the high level.

If the input remains at the low input zero for a time then the circuit will gradually return to the state shown in FIG. 2 because a leakage current 60 will leak through the right hand first pullup transistor 8-R to pull the upper plate of the right hand capacitor 6-R to VDDH (see FIG. 2). However, unlike in FIG. 4, this does not cause a floating node because the pulldown transistor 40 is still on, holding the intermediate output node 12 at the low output level 0.

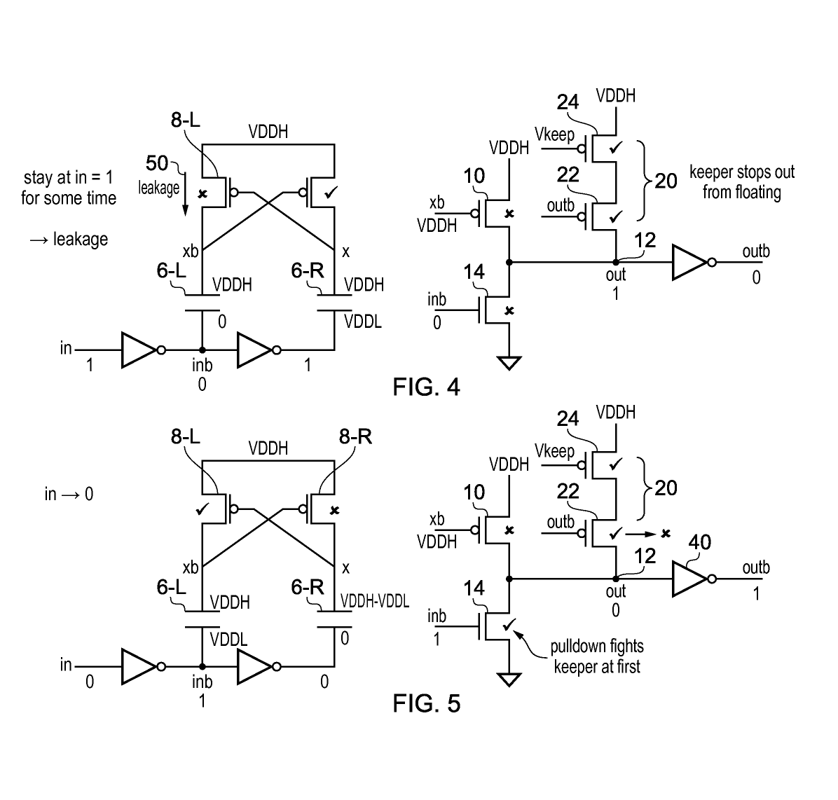

Hence, in summary the keeper circuit 20 enables correct operation even if the level conversion circuit 2 remains in the same state for long enough to be affected by the leakage current 50 through transistor 8-L. FIG. 6 shows a timing diagram illustrating the operation of the level conversion circuit 2. As shown in FIG. 6, even if the shifted signal xb begins to rise due to leakage during a period 70 while the complementary input signal inb is low, this does not affect the state of the intermediate output node out (12), which remains at the high output level as held by keeper circuit 20. Hence, the operation of the level conversion circuit is correct.

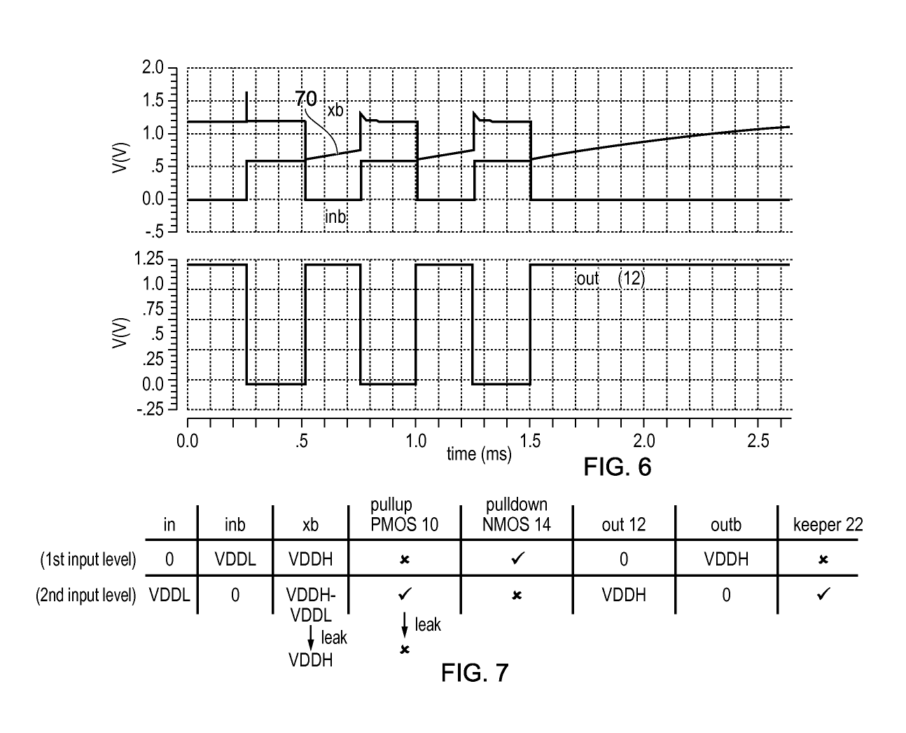

FIG. 7 shows a table summarizing the state of various signals and nodes within the level conversion circuit 2 for the two alternative values of the input signal. It will be appreciated that the relationship between the input signal in and the other signals xb, out, outb and the state of the keeper circuit 20 and pullup and pulldown transistors 10, 14 may be switched. For example, if an additional inverter is provided on the input signal then the mapping of the states of the input signal to the states of the other signals/transistors will be swapped round. Similarly, if the second pullup transistor 10 is controlled by the shifted signal x instead of the shifted signal xb then again the mapping between the input signal and the output signal would be switched. Hence, in general it is not important whether particular states of the level conversion circuit are triggered by the high input level or the low input level, since these could be reversed.

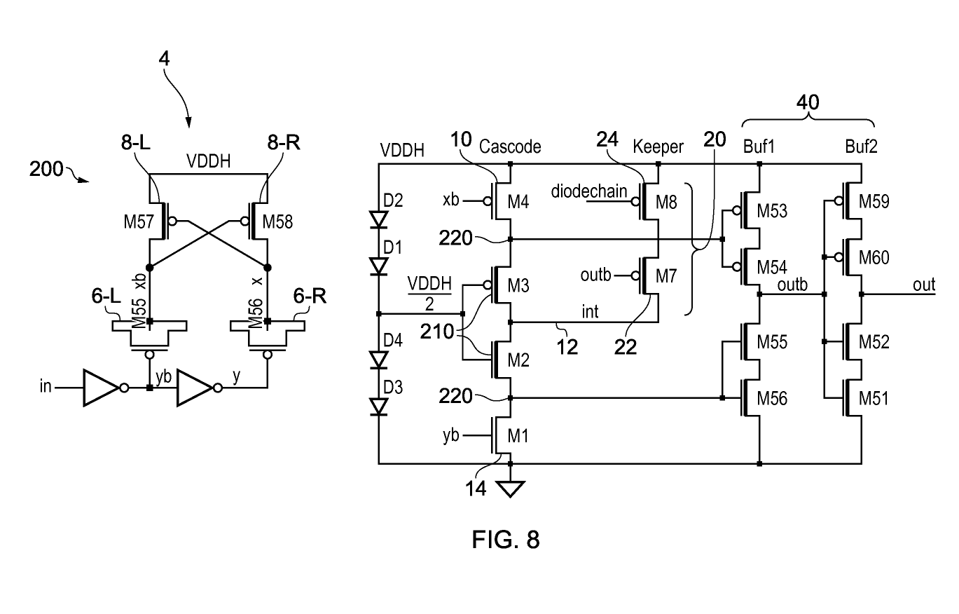

FIG. 8 shows a second example of a level conversion circuit 200 which uses thick oxide transistors and is appropriate for converting sub-threshold VDDL to input/output (I/O) level VDDH. While the circuit of FIG. 1 can be used for I/O voltages by changing all transistors to thick oxide devices having a thicker gate oxide, the performance significantly degrades in sub-threshold operations because switching speed is exponentially dependent on the overdrive voltage VDDL-Vth or VDDH-Vth, with the threshold voltage Vth of the transistors being much larger when using thicker oxide devices. To address this issue, in FIG. 8 the second pullup transistor 10 and pulldown transistor 14 are retained as thin oxide devices but the rest of the circuit is constructed from thicker oxide transistors (the thicker oxide transistors M2, M3, M51-60 are indicated in FIG. 8 using thicker lines than the thin oxide transistors M1, M4). The shifting circuit 4 is the same as in FIG. 1 except for the use of thicker oxide transistors M57, M58 as the first pullup transistors 8-L, 8-R.

To shield the thin oxide second pullup transistor 10 (M4) and the pulldown transistor 14 (M1) from drain-source breakdown caused by the higher voltages at their drains, a pair of cascode transistors 210 are provided in series between the second pullup transistor 10 and pulldown transistor 14. To leave the cascode transistors 210 always on, the cascode transistors 210 are held at a gate voltage of (VDDH/2) which is generated using a chain of diodes Dl to D4. This can be the same chain of diodes that is used in the tuning circuit 30 to generate the keeper voltage for the current regulating transistor 24. In other examples, the gate voltage of the cascode transistors need not be exactly VDDH/2. While FIG. 8 shows a single pair of cascode transistors 210, further pairs could be provided if desired.

In the example of FIG. 1 the output buffer 40 was connected directly to the intermediate output node 12. However, in the thick oxide version the intermediate output node 12 transitions slowly due to the cascode transistors 210. Instead, the upper and lower portions of the output buffer 40 are connected to external nodes 220 lying between the second pullup transistor 10 and the cascode transistors 210 and between the cascode transistors 210 and the pulldown transistor 14 respectively. These external nodes 220 transition faster than the intermediate output node 12 which is an internal node of the cascode transistors 210, and coupling the output buffer 40 to the external nodes 220 enables the output signal to transition more quickly, improving performance.

FIG. 8 shows an example in which two output buffer stages Buf1 and Buf2 are provided. Fewer or more stages may be provided if desired. For example, the second buffer stage Buf2 may be omitted. In contrast to FIG. 1, each buffer stage in FIG. 8 has a pullup portion formed of series stacked transistors M53, M54 or M59, M60 which each receive their gate voltage from the same signal. Similarly the pulldown portions are formed of series stacked transistors M55, M56 or M52, M51. Using series stacked devices in this way is useful for reducing short circuit currents. Since the switching speed of the output buffer is relatively slow for the thick oxide embodiment of FIG. 8, then as the output is ramping up or down there may be a period when both the pullup portion and the pulldown portion of an output buffer stage are on at the same time and this can cause a short circuit current passing between the VDDH and 0 rails, reducing the power efficiency of the device. By stacking several transistors in the way shown in FIG. 8, the resistance between the rails VDDH and 0 can be reduced, and hence the short circuit current can be reduced.

The operation of the level conversion circuit 200 is otherwise the same as shown in FIGS. 1 to 5. The corresponding elements indicated with the same reference numerals in FIGS. 1 and 8 operate in the same way. Even though the keeper circuit 20 of FIG. 8 is now connected to a different node 12 to the nodes 220 which are coupled to the output buffer 40, the keeper 20 nevertheless retains the node 220 at the VDDH level via the cascode transistors 210 when the complementary input signal yb is low. The design of FIG. 8 enables improved performance and power efficiency compared to earlier devices.

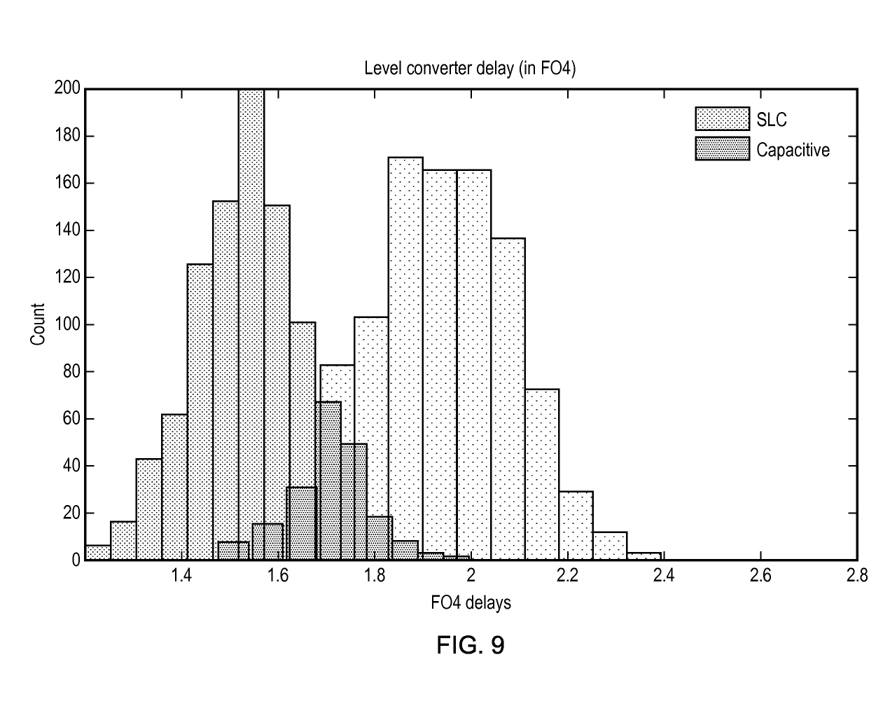

A test chip has been taped out and simulation results show performance improvements over prior art. The below results are for converting from VDDL=0.4V to VDDH=1.0V in 45 nm SOI. When the embodiment of FIG. 1 above is compared to a conventional level conversion circuit, performance is significantly improved (63 ps delay rather than 103 ps in 45 nm), and the static power of is much lower (at 1.4 uW compared to 3.4 uW) due to the small transistor sizes. Also, compared to another relatively simple circuit for subthreshold conversion, the performance over global/local variation is improved, with 25% improved mean delay and 40% improvement in delay standard deviation. FIG. 9 shows the reduced spread in FO4 delays for the capacitive level converter of FIG. 1 compared to the earlier circuit. In the example of FIG. 8 for subthreshold to I/O voltage conversion of 0.3V to 3.3V in 180 nm, the present technique can achieve a delay of 1.16 FO4 delays with static power of 67 pW, compared to a prior art circuit having delay of 1.53 FO4 with static power of 129 pW.

We claim:

1. A level conversion circuit for generating an output signal in response to an input signal, the input signal having one of a high input level and a low input level, and the output signal having one of a high output level and a low output level; the level conversion circuit comprising:
(a) a shifting circuit configured to generate a shifted signal in response to the input signal, the shifted signal having one of the high output level and an intermediate level between the high output level and the high input level;
the shifting circuit comprising a first pullup transistor configured to enter a conductive state to pull the shifted signal to the high output level when the input signal has a first input level comprising one of the low input level and the high input level, and to enter a less conductive state to allow the shifted signal to drop to the intermediate level when the input signal has a second input level comprising the other of the low input level and the high input level;
(b) a second pullup transistor configured to enter a conductive state to pull an intermediate output node to the high output level when the shifted signal has the intermediate level, and to enter a less conductive state when the shifted signal has the high output level;
(c) a pulldown transistor configured to enter a conductive state to pull the intermediate output node to the low output level when the input signal has said first input level, and to enter a less conductive state when the input signal has said second input level;
(d) an output buffer configured to generate the output signal based on the signal at the intermediate output node; and
(e) a keeper circuit configured to retain the intermediate output node at the high output level when the input signal has said second input level.

2. The level conversion circuit according to claim 1, wherein the shifting circuit comprises a capacitor coupled between a node for carrying the input signal or a complementary input signal and a shifted signal node for carrying the shifted signal.

3. The level conversion circuit according to claim 2, wherein the capacitor comprises a MOSFET.

4. The level conversion circuit according to claim 2, wherein the shifting circuit comprises first and second complementary circuits configured to generate complementary shifted signals, each of the first and second complementary circuits comprising a respective capacitor and first pullup transistor;
the capacitor of the first complementary circuit is coupled to a node for carrying the input signal;
the capacitor of the second complementary circuit is coupled to a node for carrying the complementary input signal; and
the second pullup transistor is configured to receive the shifted signal from one of the first and second complementary circuits.

5. The level conversion circuit according to claim 4, wherein the first pullup transistor of the first complementary circuit has its gate terminal coupled to the shifted signal node of the second complementary circuit; and
the first pullup transistor of the second complementary circuit has its gate terminal coupled to the shifted signal node of the first complementary circuit.

6. The level conversion circuit according to claim 1, wherein the keeper circuit comprises a keeper control transistor configured to enter a conductive state when the input signal has said second input level and to enter a less conductive state when the input signal has said first input level.

7. The level conversion circuit according to claim 6, wherein the keeper control transistor is configured to switch between the conductive state and the less conductive state in response to a complementary version of the signal at the intermediate output node.

8. The level conversion circuit according to claim 7, wherein said output buffer is configured to provide said complementary version of the signal at the intermediate output node.

9. The level conversion circuit according to claim 1, wherein the pulldown transistor is configured to pass a larger current when in the conductive state than the current passed by the keeper circuit when retaining the intermediate output node at the high output level.

10. The level conversion circuit according to claim 6, wherein the keeper circuit comprises a current regulating transistor configured to limit the current passing through the keeper control transistor when in the conductive state.

11. The level conversion circuit according to claim 10, comprising a tuning circuit configured to tune a gate voltage of the current regulating transistor to adjust the current passing through the keeper control transistor when in the conductive state.

12. The level conversion circuit according to claim 1, comprising at least one pair of cascode transistors coupled in series between the second pullup transistor and the pulldown transistor;
wherein the at least one pair of cascode transistors have a thicker gate oxide than the second pullup transistor and the pulldown transistor.

13. The level conversion circuit according to claim 12, wherein the at least one pair of cascode transistors is configured to receive a gate voltage having a level between the high output level and the low output level.

14. The level conversion circuit according to claim 12, wherein the output buffer comprises one or more buffer stages;
each buffer stage comprising a pullup portion configured to pull an output of the buffer stage to the high output level in response to a first transition of the intermediate output node between the high output level and the low output level, and a pulldown portion configured to pull an output of the buffer stage to the low output level in response to a second transition of the intermediate output node between the high output level and the low output level;
wherein the output signal comprises the output of a final buffer stage of said one or more buffer stages.

15. The level conversion circuit according to claim 14, wherein the pullup portion of a first buffer stage of said one or more buffer stages is coupled to a node between the second pullup transistor and the at least one pair of cascode transistors; and
the pulldown portion of said first buffer stage is coupled to a node between the pulldown transistor and the at least one pair of cascode transistors.

16. The level conversion circuit according to claim 15, wherein the intermediate output node comprises an internal signal node of the at least one pair of cascode transistors.

17. The level conversion circuit according to claim 14, wherein the pullup portion of each buffer stage comprises a plurality of stacked transistors coupled in series between the output of the buffer stage and a supply node for supplying the high output level; and
the pulldown portion of each buffer stage comprises a plurality of stacked transistors coupled in series between the output of the buffer stage and a supply node for supplying the low output level.

18. A level conversion circuit for generating an output signal in response to an input signal, the input signal having one of a high input level and a low input level, and the output signal having one of a high output level and a low output level; the level conversion circuit comprising:
(a) shifting circuit means for generating a shifted signal in response to the input signal, the shifted signal having one of the high output level and an intermediate level between the high output level and the high input level;
the shifting circuit means comprising first pullup transistor means for entering a conductive state to pull the shifted signal to the high output level when the input signal has a first input level comprising one of the low input level and the high input level, and entering a less conductive state to allow the shifted signal to drop to the intermediate level when the input signal has a second input level comprising the other of the low input level and the high input level;
(b) second pullup transistor means for entering a conductive state to pull an intermediate output node to the high output level when the shifted signal has the intermediate level, and entering a less conductive state when the shifted signal has the high output level;
(c) pulldown transistor means for entering a conductive state to pull the intermediate output node to the low output level when the input signal has said first input level, and to enter a less conductive state when the input signal has said second input level;
(d) output buffer means for generating the output signal based on the signal at the intermediate output node; and
(e) keeper circuit means for retaining the intermediate output node at the high output level when the input signal has said second input level.

19. A method of generating an output signal in response to an input signal, the input signal having one of a high input level and a low input level, and the output signal having one of a high output level and a low output level; the method comprising:
(a) in response to the input signal, generating a shifted signal having one of the high output level and an intermediate level between the high output level and the high input level,
the shifted signal being generated using a shifting circuit comprising a first pullup transistor configured to enter a conductive state to pull the shifted signal to the high output level when the input signal has a first input level comprising one of the low input level and the high input level, and to enter a less conductive state to allow the shifted signal to drop to the intermediate level when the input signal has a second input level comprising the other of the low input level and the high input level;
(b) switching a second pullup transistor to a conductive state to pull an intermediate output node to the high output level when the shifted signal has the intermediate level, and to a less conductive state when the shifted signal has the high output level;
(c) switching a pulldown transistor to a conductive state to pull the intermediate output node to the low output level when the input signal has said first input level, and to a less conductive state when the input signal has said second input level;
(d) retaining the intermediate output node at the high output level using a keeper circuit when the input signal has said second input level; and
(e) generating an output signal based on the signal at the intermediate output node.
